(19) United States
(12) Patent Application Publication
(10) Pub. No.: US 2025/0107048 A1
(43) Pub. Date: Mar. 27, 2025

(54) SWITCHGEAR CABINET AIR-CONDITIONING APPARATUS FOR INSTALLING OR SEMI-INSTALLING ON OR IN A DEVICE TO BE AIR-CONDITIONED

(71) Applicant: SEIFERT SYSTEMS LTD., Birzebbuga (MT)

(72) Inventors: Michael Rudi Seifert, Madliena-Malta (MT); Glenn Zammit, Ibragg-Malta (MT)

(21) Appl. No.: 18/727,675

(22) PCT Filed: Jan. 11, 2023
(86) PCT No.: PCT/EP2023/050551

§ 371 Date: Jul. 9, 2024

(30) Foreign Application Priority Data
Jan. 25, 2022 (DE) 10 2022 101 618.8
May 16, 2022 (DE) 10 2022 112 203.4

(51) Int. Cl. H05K 7/20

(52) U.S. Cl. CPC H05K 7/20609; H05K 7/20327

(57) ABSTRACT

The invention relates to a switchgear cabinet air-conditioning apparatus for installing or semi-installing on or in a device to be air-conditioned, with a large number of electronic or electrotechnical components in this device. All the air-conditioning means, including fans, compressors, heat exchangers, piping, refrigerant and evaporators are located inside the housing of the switchgear cabinet air-conditioning apparatus. The housing has means for attachment to or in a section in the device to be air-conditioned and the housing comprises a first subsection oriented towards the air-conditioning device, and a second subsection directed towards the free environment. A separation region is formed between the first and the second housing subsection, wherein all or a large majority of these air-conditioning means, which are at risk of leaking in terms of the refrigerant, are arranged in the second subsection directed towards the free environment and in a compartment formed in this regard.

The invention pertains to a switchgear cabinet air-conditioning apparatus according to the preamble of claim 1 for installation or semi-recessed installation on or in a device to be air-conditioned, wherein a plurality of electronic or electrotechnical components is arranged in said device, wherein all air-conditioning means including fans, compressors, heat exchangers, piping, refrigerant and evaporators are located within a housing of the apparatus, wherein the housing has means for being fastened on or in a section in the device to be air-conditioned, and wherein the housing comprises a first subsection oriented toward the device to be air-conditioned and a second subsection directed toward the free environment.

Switchgear cabinet air-conditioning devices or comparable apparatuses for the safe operation of electrotechnical or electronic components located in a switchgear cabinet or a similar enclosure have been known from the prior art for many years.

Such air-conditioning devices ensure a stabilization of the internal temperature in the corresponding device housing. To this effect, the heated device air is drawn in and cooled with the aid of a refrigerant. Subsequently, the correspondingly cooled air is once again delivered into the space to be cooled. Lost heat that increases the temperature can thereby be dissipated and compensated.

The refrigerant usually is compressed in a compressor. The compressor draws in the refrigerant in gaseous form. A pressure increase occurs during this process.

Subsequently, the refrigerant is pressed into a liquefier or condenser consisting of a plurality of condenser tubes by means of the compressor. The refrigerant is then cooled with the aid of supplied external air, i.e. ambient air. The refrigerant releases lost heat to the cooler air in the immediate surroundings during this process. In doing so, the temperature of the refrigerant drops and it begins to condense. The refrigerant changes its form during this process, i.e. a change from the gaseous state of aggregation to the liquid state of aggregation takes place.

The liquid refrigerant is introduced into the evaporator via a corresponding pipe connection with the aid of an expansion valve.

An evaporation of the liquid refrigerant then takes place in the evaporator. In this respect, the warm air is drawn in from the interior of the device housing and conveyed through the evaporator. The cooled air in turn is blown into the space to be cooled.

Switchgear cabinet air-conditioning devices are offered in multiple configurations, e.g. in the form of a device for being attached to a wall or a device for being installed into a wall, but also in the form of so-called roof devices that can be mounted on the upper side of a switchgear cabinet.

Dirt may be admitted into the interior of the device housing to be cooled due to the air exchange. In this respect, additional filter apparatuses are provided in many instances.

In light of the critical assessment of the chemical and physical properties of conventional refrigerants and their effects on the environment, one always strives to use refrigerants that largely are environmentally compatible.

The manufacturers of corresponding air-conditioning or refrigeration devices are increasingly confronted with F-gases Regulation No. 517/2014 of the European Union and forced to use or at least test alternative refrigerants in order to ensure the commercial viability of their own products.

In this context, it was determined that certain refrigerants by all means have very environmentally compatible properties, particularly also in instances in which refrigerant inadvertently leaks and therefore escapes from the refrigerant circuit.

However, a few of these advantageous refrigerants are respectively combustible or more or less easily inflammable.

Problems arise if a refrigerant of this type is admitted into the interior of a quasi-enclosed housing of a switchgear cabinet. For example, energizing of a contactor or a relay at this location may produce switching sparks that can lead to inflammation of the refrigerant.

The only solutions to this problem ultimately would be the implementation of explosion-proof air-conditioning devices or the arrangement of a cost-intensive sensor system in order to immediately respond to the escape of refrigerant with suitable measures for precluding an inflammation and corresponding subsequent damages.

Due to the aforementioned circumstances, the invention aims to disclose an enhanced switchgear cabinet air-conditioning apparatus for installation or semi-recessed installation on or in a device to be air-conditioned, wherein said switchgear cabinet air-conditioning apparatus is configured in such a way that it is also possible to use refrigerants that represent an inflammable or ignitable medium upon their escape or upon their transition to the gaseous state and escape.

The objective of the invention is attained with an enhanced switchgear cabinet air-conditioning apparatus according to the disclosure of claim 1, wherein the dependent claims at least represent advantageous embodiments and enhancements.

The invention therefore is based on a generally known switchgear cabinet air-conditioning apparatus that is suitable for installation or semi-recessed installation on or in a device to be air-conditioned. In this context, a device to be air-conditioned refers, for example, to a cabinet, particularly a switchgear cabinet, which contains a plurality of electronic or electrotechnical components, wherein these electronic or electrotechnical components generate lost heat or waste heat and need to be correspondingly air-conditioned.

All required air-conditioning means including fans, compressors, heat exchangers or coolers, piping, refrigerant and evaporators are located within the housing of the switchgear cabinet air-conditioning apparatus.

The housing of the switchgear cabinet air-conditioning apparatus has means for being fastened on or in a section in the device to be air-conditioned.

The housing furthermore comprises a first subsection that is oriented toward the device to be air-conditioned and a second subsection that is directed toward the free environment.

With respect to the air flow, the switchgear cabinet air-conditioning apparatus is connected to the free environment, but also indirectly connected to the interior of the device to be air-conditioned via the heat exchanger in order to discharge warm air and to allow cooled air to flow into the interior of the device to be air-conditioned.

According to the invention, a separation region, e.g. in the form of a separating plate, is formed between the first and the second housing subsections, wherein all or a large majority of the air-conditioning means, which are at risk of leaking or susceptible to leaking refrigerant, are arranged in the second subsection directed toward the free environment and a compartment formed in this regard. Only the heat exchanger is located in the air flow of the first subsection.

This means that refrigerant escaping upon a potential leak cannot be admitted into the quasi-enclosed interior of the device to be air-conditioned, but rather is discharged into the free environment.

This prevents an excessively high concentration and an inflammation of gaseous refrigerant within the device to be air-conditioned and a corresponding risk of a fire or explosion.

A concentration that would allow an inflammation cannot be formed due to the fact that the refrigerant is discharged into the environment in case of a potential leak.

Due to the proposed solution, it is possible to forgo elaborate sensors that would otherwise be required in the interior of the housing to be air-conditioned, i.e. a corresponding detection of escaping refrigerant within the device to be air-conditioned and the corresponding launch of suitable safety measures can be eliminated.

Welded, soldered, bent, welted and/or crimped sections, particularly of a refrigerant-carrying evaporator, including the associated piping preferably are arranged in the second housing subsection.

It is furthermore preferred to arrange separable refrigerant-carrying connections in the second housing subsection.

According to an embodiment of the invention, it is possible to provide a flow-conducting and/or flow-generating device in the second housing section or adjacent to this section in order to quickly and effectively remove potentially escaping gaseous refrigerant from the region of the second housing subsection, i.e. to discharge the gaseous refrigerant into the environment.

The inventive solution preferably is suitable for the use of combustible or easily inflammable refrigerants.

The device to be air-conditioned and its housing essentially are closed or can be closed. Since it is possible to forgo a forced flow through the device, e.g. in the form of a switchgear cabinet, namely also in the case of a conceivable admission of combustible refrigerant into the device housing in accordance with the prior art, the constructive design of the corresponding housing is simplified and compartmentalization measures for the use under critical environmental conditions or in an industrial environment can be eliminated.

If a potential escape of refrigerant is detected based on a significant refrigerant pressure loss, the invention naturally also provides the option of delivering a fault message or triggering an alarm in order to restore the operability of the air-conditioning device on the one hand and to prevent the escape of additional refrigerant on the other hand, namely in such a way that no excessively high concentration of refrigerant exists in the immediate surroundings of the air-conditioning device.

With respect to the piping for an evaporator or heat exchanger, it should at this point be noted that it is not necessary to arrange the entire piping in the second housing subsection. In fact, it is perfectly adequate to position the pipe connecting points produced, for example, by means of soldering or sections that are particularly prone to breakage in this region.

An exemplary embodiment of the invention is described in greater detail below with reference to the figures.

In these figures:

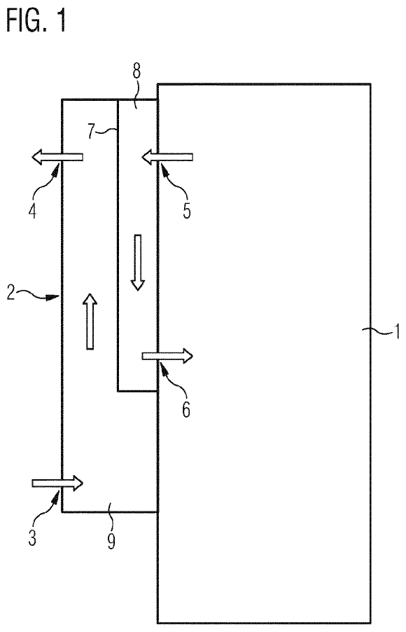

FIG. 1 shows a schematic diagram of an exemplary switchgear cabinet with an air-conditioning apparatus coupled thereto;

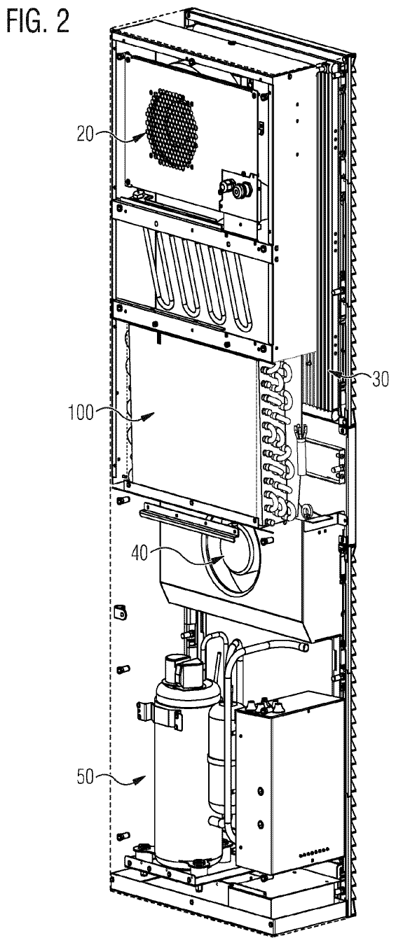

FIG. 2 shows a perspective view of the air-conditioning apparatus for installation on a (not-shown) exemplary switchgear cabinet with omitted cover and the main assemblies, and

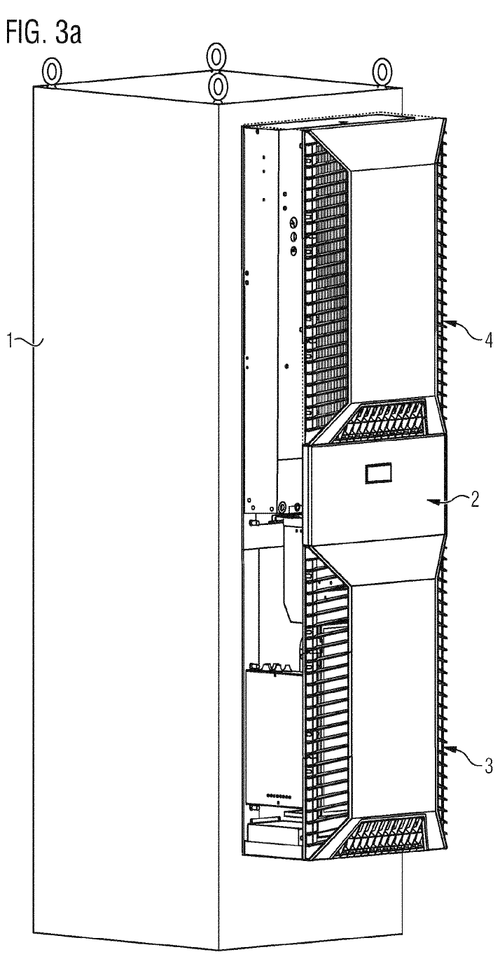

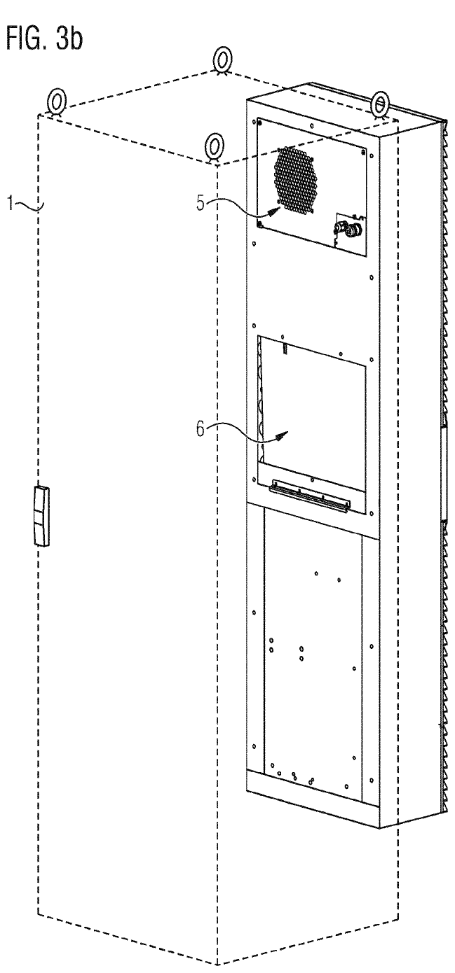

FIGS. 3a, b show illustrations of an exemplary switchgear cabinet with attached air-conditioning apparatus (FIG. 3a), as well as an illustration of the contours of a switchgear cabinet (dot-dashed line) with an air-conditioning apparatus coupled thereto and the visible connecting sections for the cooling air flow with air inlet and air outlet.

According to the schematic diagram illustrated in FIG. 1, the invention is based on a device 1 to be air-conditioned, e.g. a switchgear cabinet, which contains a plurality of electronic and electrotechnical components within its switchgear cabinet housing. It is necessary to cool these electronic or electrotechnical components, i.e. to respectively dissipate the lost heat being generated or to ensure heating of the interior of the switchgear cabinet in order to prevent dew point effects.

A sidewall of the device 1 has two apertures that are spaced apart from one another. A first aperture 5 conducts a flow of discharge air out of the interior of the device 1.

A second aperture 6 conducts cooled or conditioned air into the interior of the device 1.

The actual air-conditioning apparatus 2 has a separation region 7.

This separation region 7 forms a first subsection or subspace 8.

This first subsection 8 has complementary openings referred to the apertures 6 and 7 in order to allow a corresponding cooling air flow.

A corresponding fan (which is not illustrated in FIG. 1) is provided in order to generate the air flow.

The second subsection 9, which is separated from the first subsection 8 by the separation region 7, has an ambient air inlet 3, as well as a corresponding ambient air outlet 4.

All or a large majority of the air-conditioning means, which are at risk of leaking or susceptible to leaking refrigerant, are installed in the second subsection 9. A compartment that is separated from the first subsection 8 consequently is formed.

Among other things, a compressor and an evaporator with associated line connections (see FIG. 2) are arranged in this separated compartment.

The air-conditioning apparatus 2 can be conventionally fastened on the housing of the device 1 with mechanical connecting means.

FIG. 2 shows an air-conditioning apparatus used in accordance with the invention without its enclosure.

The air-conditioning apparatus has a compressor 50, a first fan 40, a cooler or heat exchanger 30, an evaporator 100 and a second fan 20.

The second fan 20 ensures the flow in the region of the first subsection 8 and conducts cooled or conditioned air into the interior of the device 1 (see FIG. 1, in which arrows symbolize the flow directions).

As an example, FIGS. 3a and 3b show how an air-conditioning apparatus 2 can be coupled to a device, in the example shown an indicated switchgear cabinet housing, on a corresponding sidewall.

FIG. 3b elucidates the arrangement of the apertures for realizing the internal flow.

Ambient air is drawn in through the opening 3 and once again discharged in the region of the opening 4. The reference symbols 5 and 6 in FIG. 3b correspond to the illustrations with the reference symbols 5 and 6 in FIG. 1.

1. A switchgear cabinet air-conditioning apparatus for installation or semi-recessed installation on or in a device (1) to be air-conditioned, wherein a plurality of electronic or electrotechnical components is arranged in said device (1), wherein all air-conditioning means including fans (20; 40), compressors (50), heat exchangers (30), piping, refrigerant and evaporators (100) are located within a housing, wherein the housing has means for being fastened on or in a section in the device (1) to be air-conditioned, and wherein the housing comprises a first subsection (8) oriented toward the device (1) to be air-conditioned and a second subsection (9) directed toward the free environment,
characterized in that
a separation region (7) is formed between the first and the second housing subsections (8; 9), wherein all or a large majority of the air-conditioning means, which are at risk of leaking or susceptible to leaking refrigerant, are arranged in the second subsection (9) directed toward the free environment and a compartment formed in this regard.

2. The switchgear cabinet air-conditioning apparatus according to claim 1,
characterized in that
welded, soldered, bent, welted and/or crimped sections, particularly of a refrigerant-carrying evaporator (100), including the associated piping preferably are arranged in the second housing subsection (9).

3. The switchgear cabinet air-conditioning apparatus according to claim 1,
characterized in that
separable refrigerant-carrying connections are arranged in the second housing subsection (9).

4. The switchgear cabinet air-conditioning apparatus according to claim 1,
characterized in that
a flow-conducting and/or flow-generating device is provided in or on the second housing section (9) in order to quickly and effectively discharge potentially escaping gaseous refrigerant from the region of the second housing subsection into the environment.

5. The switchgear cabinet air-conditioning apparatus according to claim 1,
characterized in that
a combustible refrigerant can be used.

6. The switchgear cabinet air-conditioning apparatus according to claim 1,
characterized in that
the housing of the device (1) to be air-conditioned essentially is closed or can be closed.
